(19) United States
(12) Patent Application Publication
(10) Pub. No.: US 2020/0218957 A1
(43) Pub. Date: Jul. 9, 2020

(54) RFID-CARREL

(71) Applicant: Jari NOKKALA, Hyvinkää (FI)

(72) Inventor: Jari NOKKALA, Hyvinkää (FI)

(21) Appl. No.: 16/648,596

(22) PCT Filed: Sep. 18, 2018
(86) PCT No.: PCT/FI2018/050678

§ 371 Date: Mar. 18, 2020

(30) Foreign Application Priority Data
Sep. 18, 2017 (FI) 20177106
Feb. 20, 2018 (FI) 20185156

(51) Int. Cl. G06K 19/073; G06K 7/10; H05K 9/00

(52) U.S. Cl. CPC G06K 19/07327; H05K 9/0015; H05K 9/0001; G06K 7/10009

(57) ABSTRACT

The invention relates to a reading carrel for RFID tags, having a ceiling, a floor, at least one door, as well as walls encircling the reading carrel and including a plurality of interconnected wall elements, as well as a mounting frame for the walls and the at least one door, as well as means for reading RFID tags in the reading carrel. The reading carrel has a mounting frame comprising a horizontal base extending around an interior of the reading carrel and consisting of a plurality of interconnected base segments, said base being provided with a plurality of vertical supports. Each base segment of the mounting frame is made up of a channel beam and each vertical support is also made of a channel beam, said channel beams having channels thereof consisting of a channel base which is provided on both sides with channel flanges directed away from said channel base, each channel flange extending in a direction transverse to that of said channel base. Each wall element of the wall has its bottom end fitted in the channel of the mounting frame's base and, moreover, each wall has both end faces thereof fitted in the channel of the mounting frame's vertical support. Between at least one base segment as well as a bottom end of the wall element mounted thereon is fitted a radio-frequency interference suppressing seal, such as an EMC gasket, which extends co-directionally with the channel base of a channel beam comprising said base segment, whereby between at least one vertical side face adjoining at least one end face of a wall element mounted on said base segment and the channel flange of the channel of the channel beam comprising the vertical support mounted on the very same base segment is likewise fitted a radio-frequency interference suppressing seal, such as an EMC gasket, which extends co-directionally with the channel base of the channel beam comprising said vertical support, such that the aforesaid radio-frequency interference suppressing seal extends in a substantially continuous manner from the base segment to the channel flange of at least one vertical support. Reading means for RFID tags comprise an antenna as well as a data processing system, both of which provide a capability of reading RFID tags.

The invention relates to a reading carrel for RFID tags as defined in the preamble of claim 1.

The invention also relates to a reading carrel for RFID tags as defined in claim 15.

Reading carrels for RFID tags should be as interference-free as possible for external radio frequency radiation and yet the reading sensitivity in the carrel should be as good as possible. These are conflicting objectives because increasing the reading sensitivity for RFID tags in a carrel also increases sensitivity for RFID tags external of the carrel. By merely improving the manufacturing tolerance and sealing of component parts it is difficult to improve the insulation of a carrel without also increasing significantly manufacturing/assembly costs for the carrel.

Another drawback involved in the foregoing is the fact that increasing insulation thoroughness leads to a dramatic reduction of installation speed, because the construction of insulations between a mounting frame and walls is the more laborious the better the desired insulation.

With the above prior art as a starting point, it is an objective of the invention to provide a reading carrel for RFID tags, which would be as least sensitive as possible to reading disorders caused by extra-carrel RFID tags, yet which would not require excessively tight manufacturing tolerances to be provided for the walls and the mounting frame. A further intention in the invention was to provide a reading carrel, wherein insulation between a mounting frame (base beams, vertical supports and top supports) and the walls would be simple and quick to install.

The invention relates to a reading carrel for RFID tags as defined in claim 1.

More specifically, the invention relates to a reading carrel for RFID tags, having a ceiling, a floor, at least one door, as well as walls encircling the reading carrel and including a plurality of interconnected wall elements, as well as a mounting frame for the walls and the door/doors, as well as means for reading RFID tags in the reading carrel. Thus, the reading carrel has its
mounting frame comprising a horizontal base extending around an interior of the reading carrel and consisting of a plurality of interconnected base segments, said base being provided with a plurality of vertical supports, whereby
   each base segment as well as vertical support of the mounting frame are made of a channel beam, said channel beams having channels thereof consisting of a channel base which is provided on both sides with channel flanges directed away from the channel base, each channel flange extending in a direction transverse to that of the channel base,
   each wall element of the wall has its lower end fitted in the channel of the mounting frame's base and, moreover, each wall has both end faces thereof fitted in the channel of the mounting frame's vertical support,
between at least one base segment and a bottom end of the wall element mounted thereon is fitted a radio-frequency interference suppressing seal, such as an EMC gasket, which extends co-directionally with the channel base of a channel beam comprising said base segment, whereby between at least one vertical side of a wall element mounted on said base segment and the channel flange of the channel of the channel beam comprising the vertical support mounted on the very same base segment is likewise fitted a radio-frequency interference suppressing seal, such as an EMC gasket, which extends co-directionally with the channel base of the channel beam comprising said vertical support, such that the aforesaid radio-frequency interference suppressing seal extends in a substantially continuous manner from the base segment to the channel flange of the vertical support,
reading means for RFID tags comprise an antenna as well as a data processing system, both of which provide a capability of reading RFID tags.

In a preferred embodiment of the invention, the mounting frame further comprises a horizontal top support for the mounting frame, which is associated with a top end of the vertical supports, and which top support consists of a channel beam, having its channel made up of a channel base which is provided on both sides with channel flanges directed away from the channel base, each in a direction transverse to that of said channel base,
one of the channel flanges of the top support is fitted with a radio-frequency interference suppressing seal, such as an EMC gasket, which extends co-directionally with the channel beam's channel base,
each wall element of the wall has its top end fitted in the channel of the mounting frame's top support in such a way that the aforesaid radio-frequency interference suppressing seal rests respectively on a top end of the flange.

The invention relates also to a reading carrel for RFID tags as defined in claim 15.

More specifically, the invention also relates to a reading carrel for RFID tags, having a ceiling, a floor, at least one door, as well as walls encircling the reading carrel and including a plurality of interconnected wall elements, as well as a mounting frame for the walls and the door/doors, as well as means for reading RFID tags in the reading carrel, the mounting frame comprising a horizontal base extending around an interior of the reading carrel and consisting of a plurality of interconnected base segments. This base is provided with a plurality of vertical supports, each base segment as well as vertical support of the mounting frame being respectively made of a beam provided with a web which is directed upwards from the beam's horizontal plane or sideways from the beam's vertical plane and which extends in a longitudinal direction of the discussed beam.

The wall element has its bottom end, as well as both of its end faces, provided with an elongated channel which is made up of a channel base provided on both sides thereof with channel flanges directed away from the channel base, each extending in a direction transverse to that of said channel base, whereby
the wall element has the channel of its lower end and the channels of both end faces thereof fitted respectively on the web of a base segment in the mounting frame and on the web of a vertical support.
between the lower end channel of each wall element of the wall and the web of a base segment of the mounting frame is fitted at least one radio-frequency interference suppressing seal, such as an EMC gasket, which extends co-directionally with the channel base, and
between the channel of a wall element's each end face and the web of a respective vertical support is also fitted at least one radio-frequency interference suppressing seal, such as an EMC gasket, which extends in a lengthwise direction of the vertical support,
reading means for RFID tags comprise an antenna as well as a data processing system, both of which provide a capability of reading RFID tags.

In one preferred embodiment of the invention defined in claim 15, the mounting frame further comprises a top support, which is co-directional with the base of the mounting frame and associated with a top end of the vertical supports, and said top support consists of a beam which includes a web directed downward from the beam's horizontal plane and extending co-directionally with a longitudinal direction of the top support, whereby the wall has a top end of its wall elements and/or the door frame has a top end of its head piece provided with an elongated channel, which is made up of a channel base provided on both sides thereof with channel flanges directed away from the channel base, each extending in a direction transverse to that of said channel base,
each wall element of the wall has its top end channel and/or the door frame has the top end channel of its head piece fitted on said web of the mounting frame's top support,
between at least one channel flange of the top end channel of each wall element of the wall and the web of the top support is fitted an elongated radio-frequency interference suppressing seal, such as an EMC gasket, which extends co-directionally with the top end channel of said wall element.

It is a basis of the invention that a reading carrel for radio-frequency tags used for the remote identification of radio-frequency tags (I.e. so-called RFID tags) has been successfully made interference-free in terms of reading disorders caused by extra-carrel RFID tags by concentrating possible fabrication inaccuracies of the walls in a mounting frame's channel which is included in the mounting frame's base and vertical supports, as well as in the top support. Alternatively, the fabrication inaccuracies of the base are concentrated in channels included in wall elements of the walls.

Hence, it is possible to make allowances in the manufacturing accuracy of either wall elements or a mounting frame and nevertheless to achieve interference suppression considerably better than at present inside a reading carrel for RFID tags. Thereby is attained the significant benefit of being able to enhance the reading accuracy of an RFID tag reader without being exposed to reading disorders generated by RFID tags external of the reading carrel.

In one preferred embodiment of the invention, the reading carrel according to the invention has at least one door, including a door element as well as a door frame encircling the door element. The door frame has its bottom piece fitted in a channel of the mounting frame's base. In addition, the door frame has each of its side pieces fitted in a channel of the mounting frame's vertical support in such a way that said radio-frequency interference suppressing seal is resting respectively against the door frame's bottom piece or against the door frame's side piece.

In another preferred embodiment of the invention, the reading carrel according to the invention has at least one door, including a door element as well as a door frame encircling the door element. The bottom piece of the door frame and each side piece of the door frame are provided with a channel, which is made up of a channel base provided on both sides thereof with channel flanges directed away from the channel base, each extending in a direction transverse to that of said channel base. Hence, in at least one of the channel flanges of a channel in the door frame's bottom piece, and in at least one of the channel flanges in each side piece thereof, is fitted a radio-frequency interference suppressing seal, such as an EMC gasket, which extends co-directionally with the channel base of said channel. Thus,
the door frame has each of its side pieces fitted on the web of the mounting frame's vertical support in such a way that the aforesaid at least one radio-frequency interference suppressing seal is also in contact with the web of the mounting frame's vertical support, and
the door frame has its bottom piece fitted on a base segment of the mounting frame's base in such a way that the aforesaid at least one radio-frequency interference suppressing seal is also in contact with a web included in the base segment of the mounting frame's base.

The inventor has discovered that the biggest problems in a reading carrel for RFID tags are caused by the departure of external radio-frequency signals from the reading carrel by way of inadequate door seals. In relation to doors, the invention makes use of a system concentrating fabrication inaccuracies similar to that used in connection with wall elements and a base of the mounting frame; possible fabrication inaccuracies of the door are concentrated in the mounting frame's channel or in channels included in the door frames.

The radio-frequency interference suppressing seal refers to an elongated gasket fabricated from an electrically conductive material such as metal. One typical electrically conductive EMC gasket is a sealing strip made of aluminum. Insulation can also be achieved with mutual form-locking/form-pressing parts of the wall elements and the mounting frame provided that either or both of the wall elements and the mounting frame are manufactured from an electrically conductive material, regarding at least those parts thereof which come into mutual contact.

The radio-frequency interference refers to radio-frequency interference waves with a wavelength of 3 Hz-300 GHz.

In one preferred embodiment of the invention, the interference-suppressing seal extends in a continuous manner from a channel flange of the channel in the mounting frame's base to a channel flange of two vertical supports associated therewith, and further to a channel flange of the possible top support.

When the mounting frame provided with such a mounting frame sealing has installed thereon a wall element, the attained benefit will be that of establishing a continuous insulation encircling the wall element's front side and preventing effectively radio-frequency waves from entering the reading carrel.

In yet another preferred embodiment of the invention, the radio-frequency interference suppressing seal extends in a continuous manner from the web of a base segment in the mounting frame's base to the web of a vertical support, and further to the web of a possible top support.

When the mounting frame's web, provided with such a mounting frame insulation, has fitted thereon a wall element's end sides, as well as its horizontal bottom and top sides, the attained benefit will be that of establishing a continuous insulation encircling the wall element's end side as well as its bottom and top sides and preventing effectively radio-frequency waves from entering the reading carrel.

In still another preferred embodiment of the invention, the radio-frequency interference suppressing seal extends in a continuous manner from a channel flange of the channel in the mounting frame's base to a channel flange of two vertical supports associated therewith, and further to a channel flange of the door frame support's channel.

In still another preferred embodiment of the invention, the radio-frequency interference suppressing seal extends in a continuous manner from the web of a base segment in the mounting frame's base to the web of a vertical support, and further to the web of a door frame support.

When the mounting frame, provided with such a sealing, has installed thereon a wall element as well as a door frame, the attained benefit will be that of establishing between the wall element and the door frame an insulation which prevents radio-frequency waves from entering the reading carrel by way of the wall element and/or the door frame.

The concept “the seal extends in a continuous manner” is used in reference to a sealing possibly including rather minuscule voids left inside the seal, but not outright discontinuities at which the sealing would have been disrupted.

It is by using a mounting frame of the invention, including channel beams, on which can be mounted a wall element or wall elements, provided with channels in which can be fitted webs of the mounting frame, that there is obtained a structure capable of being sealed easily and with extraordinary speed; the sealing is easy to install so as to encircle the mounting frame as well as the wall elements' channels/webs.

The invention will now be described more precisely with reference to the accompanying figures.

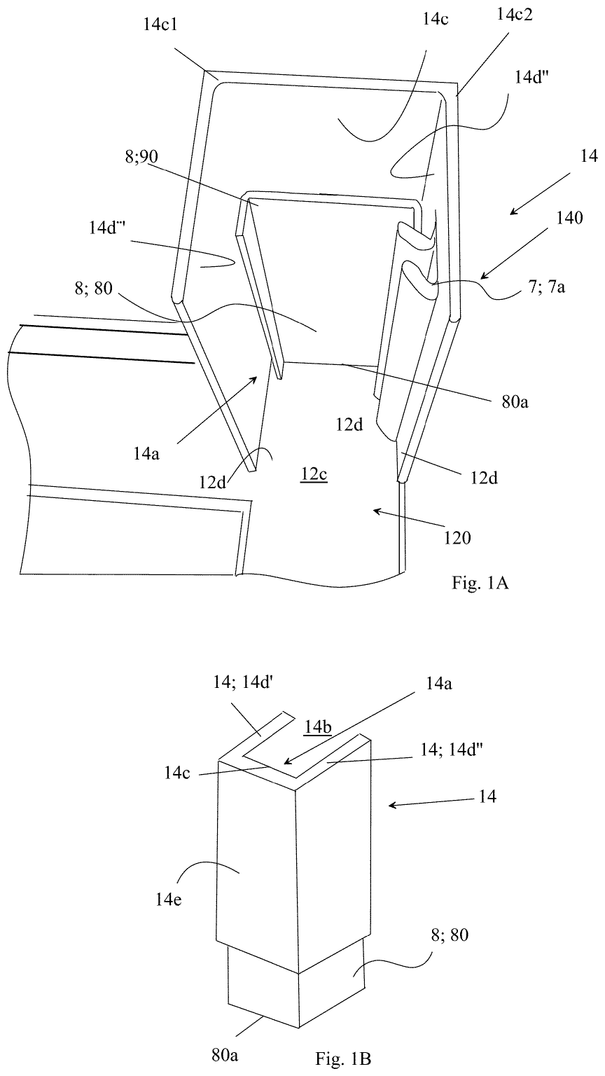

FIG. 1A shows, in a view diagonally from above, a top support installed on a mounting frame's base.

FIG. 1B shows, in a schematic perspective view, the top support as seen from behind.

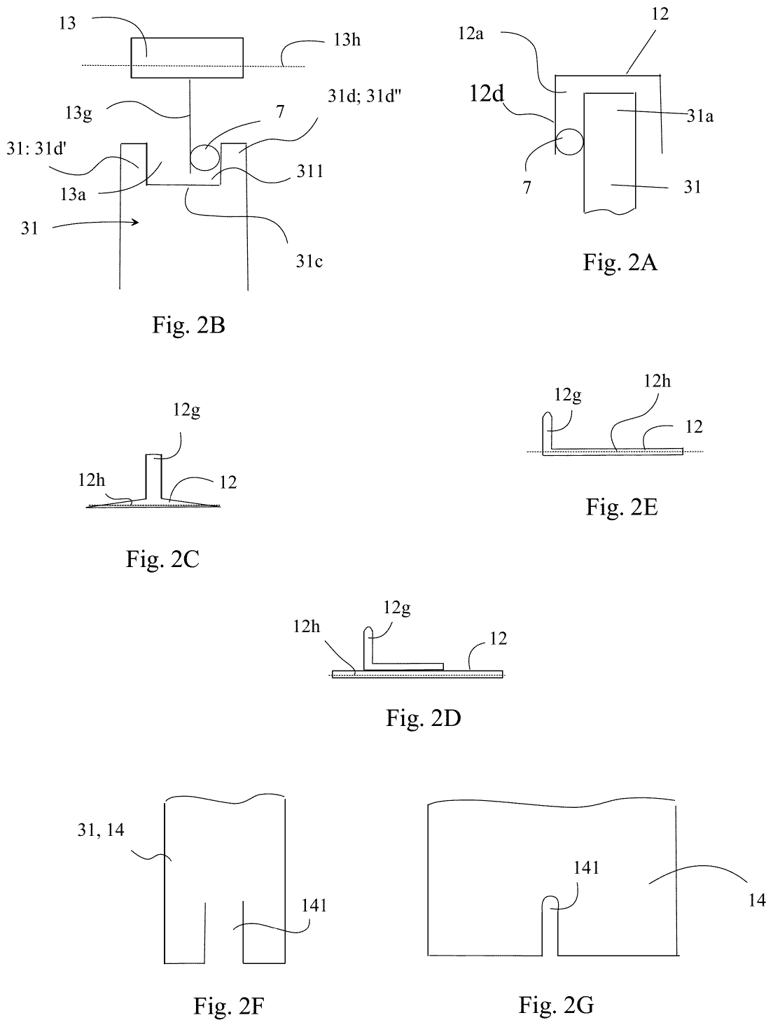

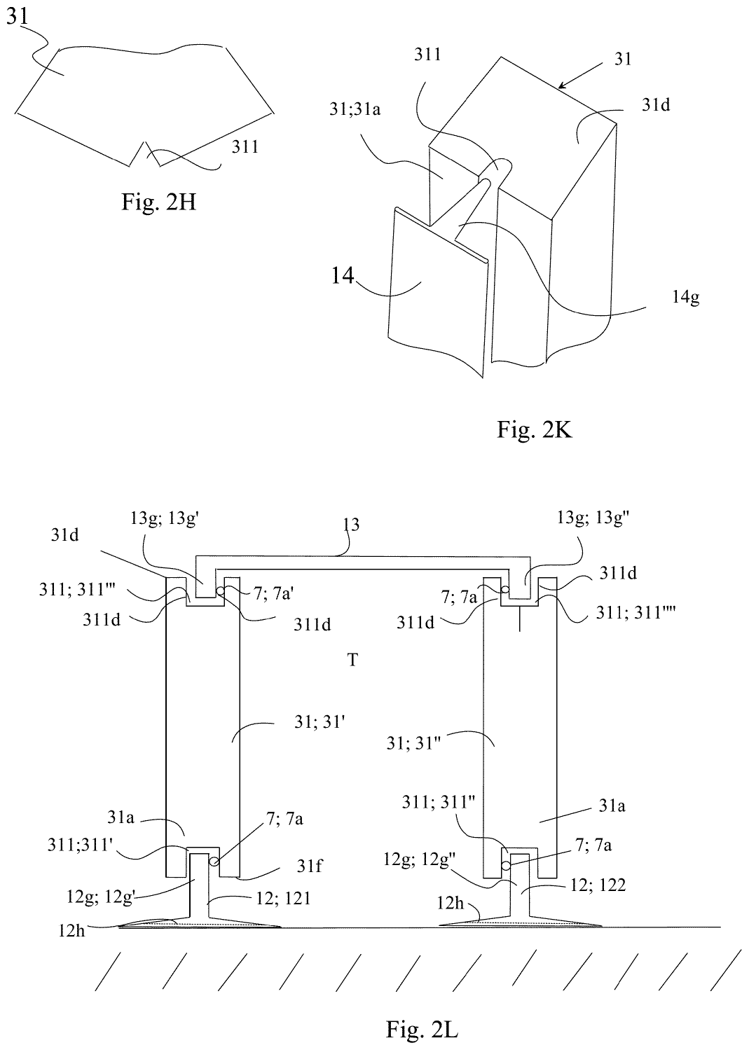

FIGS. 2A and 2B show schematically two principles of channel sealing for the mounting frame's beams.

FIGS. 2C-2H show schematically various sealing systems for a web present in a beam of the mounting frame and for a channel present in the wall.

FIGS. 2K and 2L depict schematically assemblies made up by a web and a channel in the mounting frame's top support and walls.

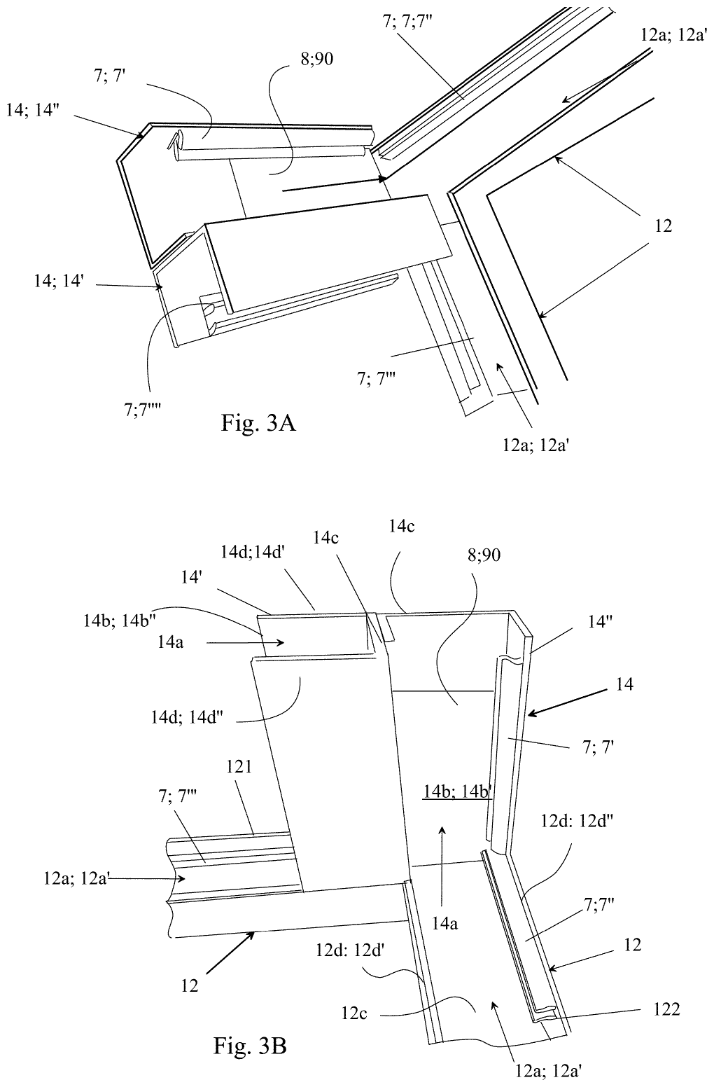

FIGS. 3A and 3B show, in a diagonal view from above, the way a vertical support is installed in a corner of the mounting frame's base, as well as a completed corner of the base provided with a vertical support.

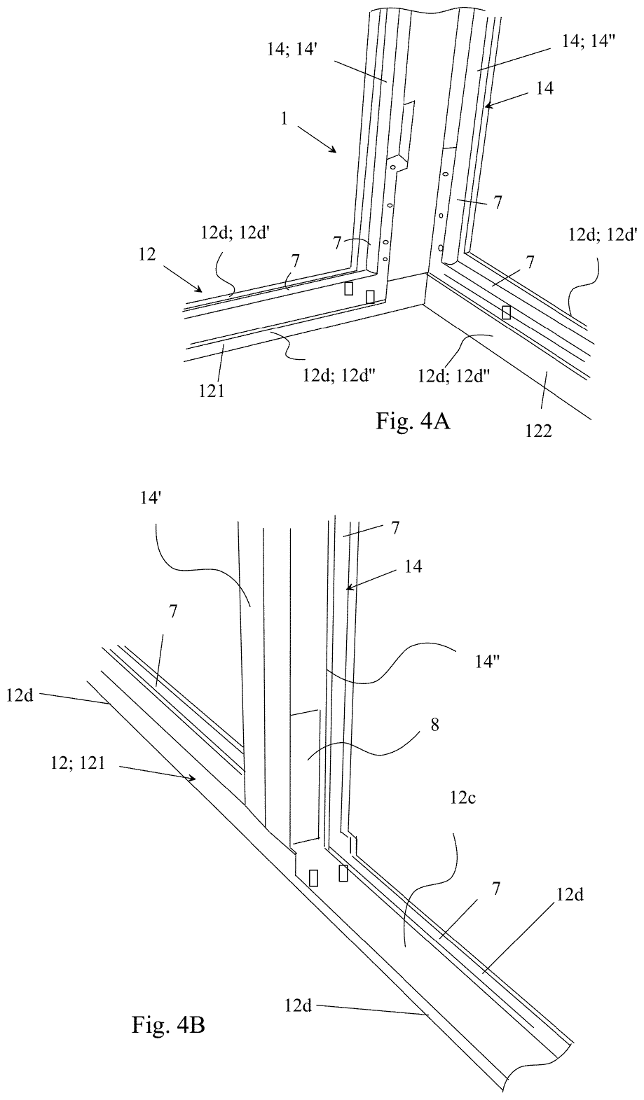

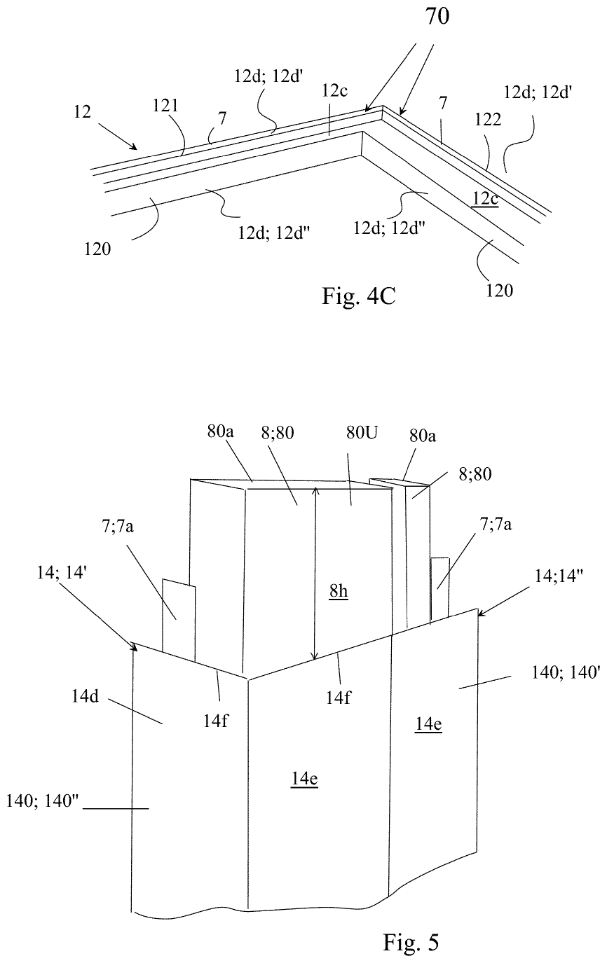

FIGS. 4A and 4B illustrate, in a perspective view, various vertical supports installed both on a straight section of the mounting frame's base segment and in a corner of the base.

FIG. 4C illustrates schematically the way a corner of the mounting frame's base is constructed from two base segments.

FIG. 5 shows, in a lateral view, the end face of a vertical support provided with an end face adapter for installing a vertical support on the mounting frame's base or on the mounting frame's top support.

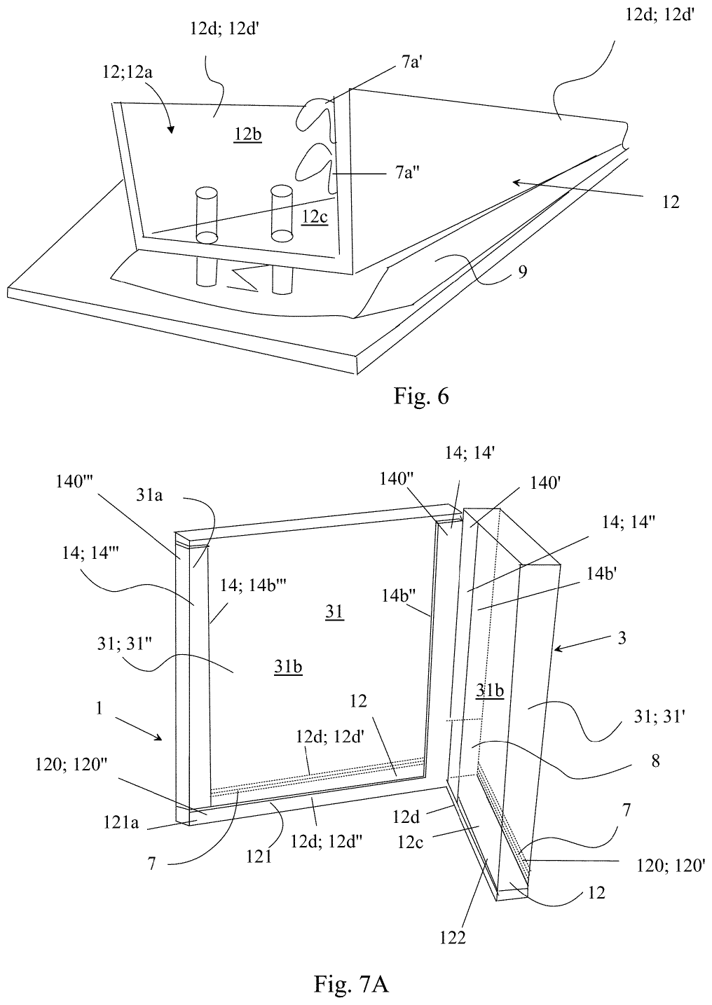

FIG. 6 shows, in a diagonal lateral view, the way of adjusting the mounting frame's base by means of an auxiliary mounting frame.

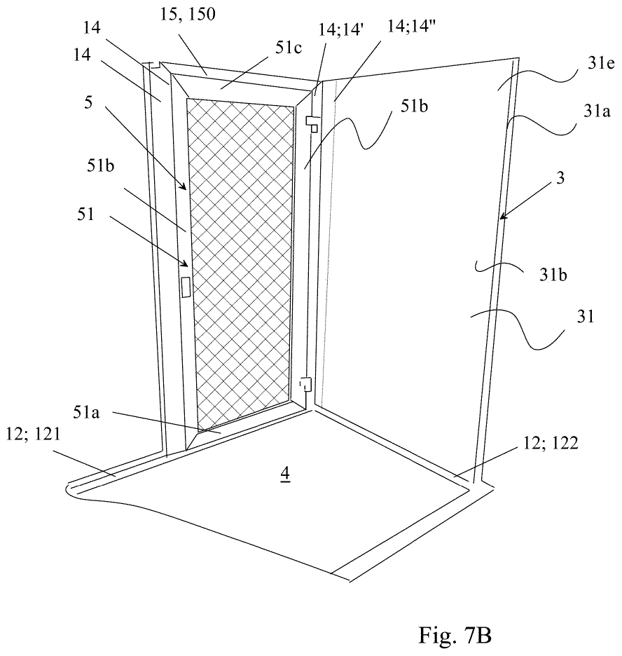

FIGS. 7A and 7B show, in a diagonal front view, a part of two different reading carrels for RFID tags.

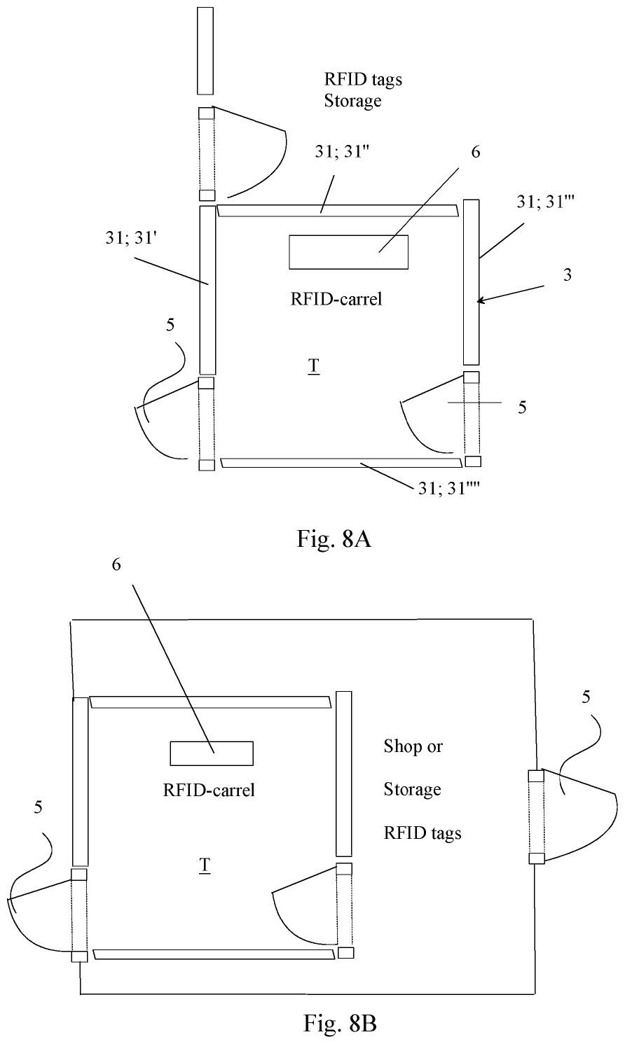

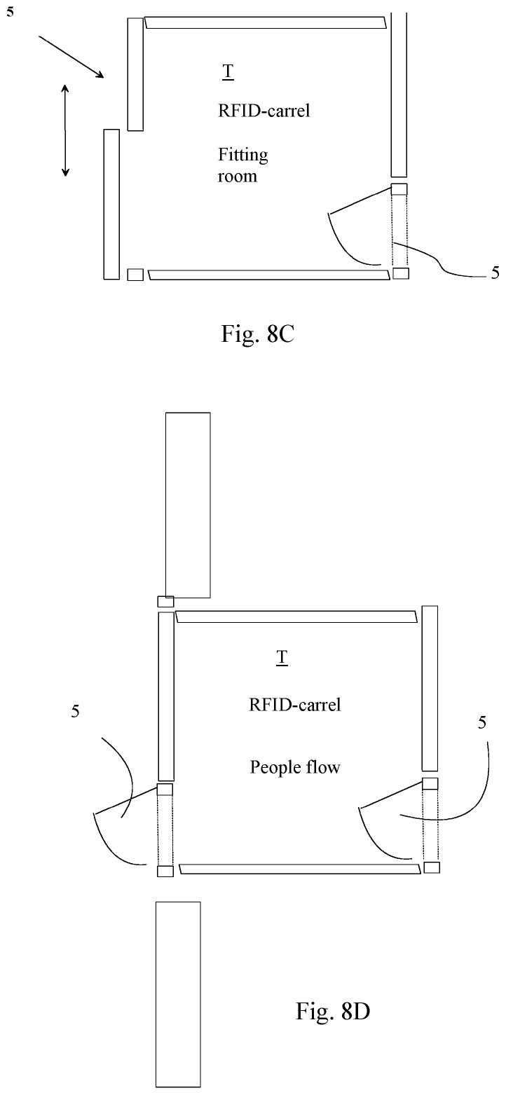

FIGS. 8A-8D illustrate, in a view from above, various mounting frame configurations for constructing an RFID-carrel.

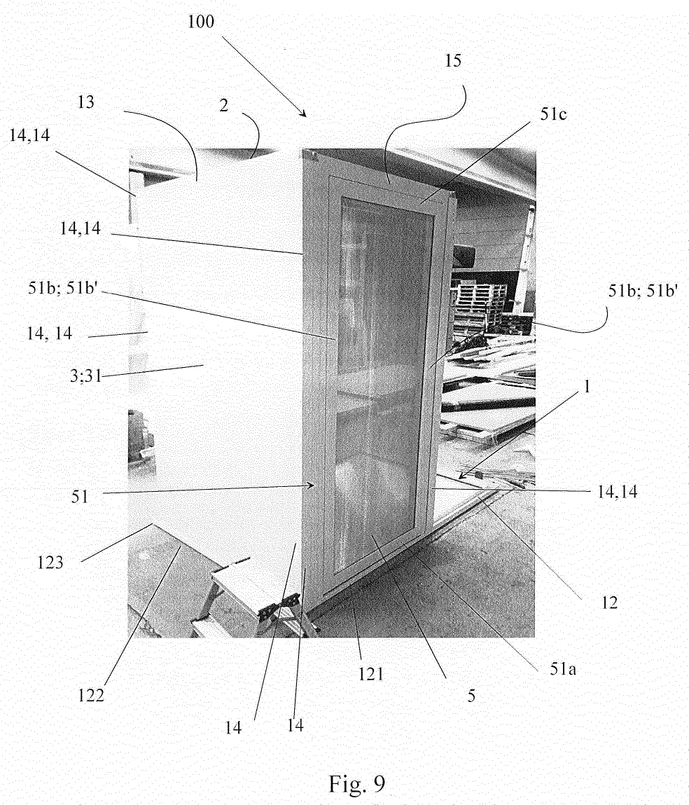

FIG. 9 illustrates, in a view from outside, one completed reading carrel for RFID tags.

Constructions used in connection with a mounting frame 1 of the invention for a vertical support 14. a mounting frame-encircling base 12, a top support 13, a door frame support 15, and wall elements 31 of walls 3 are illustrated in FIGS. 1A-1B, 2A-H, 2K, 2L, 3A-3B, 4A-4C, 5, as well as 6.

These basic constructions of the mounting frame 1 enable assembly of various reading carrels for RFID tags as depicted in FIGS. 7A-7B, 8A-8D, and 9.

Hereinafter is first described, schematically by way of FIGS. 1A-1B and 2A-2H, 2K, 2L, constructions as well as sealing options for the mounting frame 1 and wall elements connected therewith.

In FIGS. 2A and 2B is illustrated with two section views, respectively, the construction of two similar type sealings either

a) by placing a gasket 7 between a channel beam (120, 130 or 140) and a wall element 31 or

b) by placing a gasket 7 between a wall element 31 provided with a channel 311 and a web 13g extending from a beam 13 (vertical support).

The exemplary sealing visible in FIG. 2A is constructed by placing the gasket 7 between a U-channel 12a of the base 12 comprising a channel beam and a bottom end of the wall element 31 fitted in this U-channel 12a. A similar type sealing can also be constructed by installing a gasket between a U-channel of the top support 13 comprising a channel beam and a top end of the wall element 31 or between a U-channel of the vertical support 14 and an end face of the wall element 31. As evident from FIG. 2A, the gasket is usually placed between a bottom end of the wall element 31 adjoining the lower end face thereof and just one of the channel flanges of the U-channel in a base segment.

The exemplary sealing visible in FIG. 2B is constructed between a web 13g directed downward from the beam of the top support 13 and a horizontal channel 31a extending at a top end of the wall element 31 co-directionally with the top end of the wall element 31, said horizontal channel opening upward. The top support 13 has its web 13g brought to the proximity of a channel base 31c of the horizontal channel 31a at the top end of the wall element 31. The gasket 7 is placed between a channel flange 31d; 31d″ and the web 13g, the former extending upward from the horizontal channel's channel base 31c. An exactly similar type sealing can likewise be constructed between a web 12g directed upward from a base segment of the base 12 and a horizontal channel 311 included in a bottom end of the wall element 31 and opening downward, or between a web directed sideways from a vertical support 14 co-directionally with the vertical support and an end channel 311 included in an end face of the wall element 31 and opening sideways.

FIG. 1B illustrates one way of placing a gasket 7 on a channel beam 140, said channel beam 140 being then usable for constructing the sealing of FIG. 2A between the channel beam 140 and the bottom end 31 of a wall element as subsequently described.

In FIG. 1B is shown (in a view from behind) a channel beam 140 that can be used as a vertical support 14. From below a bottom edge of the channel beam 140 extends an end adapter 8; 80 directed downward in FIG. 1B and being narrower than the rest of the beam body. The illustrated channel beam 140 is capable of being rested by way of a bottom end bearing surface 80a of its end adapter 80 against a channel base 12c of the base segment's channel beam 120 as depicted in FIG. 1A.

The vertical support 14 visible in FIG. 1B consists of a channel beam 140 having its U-shaped channel 14a (U-channel) made up of a channel base 14c both lengthwise sides of which are provided with a channel flange 14; 14d′ and 14; 14d″ pointing away from the channel base 14c. Each channel flange 14; 14d′ and 14; 14d″ of the vertical support 14 extends away from the channel base 14c of the U-channel 14a at an angle of about 90 degrees, whereby the plane extending by way of each channel flange 14; 14d′ and 14; 14d″ is transverse relative to the direction of the channel base's 14c plane.

In FIG. 1A is shown a channel beam 140 of FIG. 1B (vertical support 14), including a U-channel 14a. This U-channel 14a connects to the base 12 by way of an adapter 8. The adapter 8 comprises an inner adapter 8; 90 for the vertical support 14 and an end face adapter 8; 80a joining seamlessly with the inner adapter. The end face adapter 8; 80a is rested against a channel base 12c of the channel 12a in the mounting frame's base 12.

In FIG. 1A, it is only along one of the two channel flanges 14d; 14d″ of the vertical support 14 that, co-directionally with the channel base 14, i.e. in vertical direction, extends a continuous EMC gasket 7; 7a, which is approximately equal in length to said channel flange 14; 14d″ and which conducts electricity. The EMC gasket is suitably an aluminum strip.

The EMC gasket has an objective of sealing, as illustrated in FIG. 2A, a clearance left between a wall element 31 mountable on the vertical support 14 and a channel flange 14d of the vertical support's U-channel, such that the EMC gasket 7; 7a does not allow passage of radio-frequency radiation therethrough from inside to outside of the carrel or vice versa. As can be seen from FIG. 1A, once the vertical support 14 is rested by way of the end face adapter 8; 80 against the channel base 12c of the mounting frame's base 12, the vertically directed EMC gasket extends all the way to a channel flange 12d of the base 12. On this channel flange 12d is then installed its own EMC gasket in horizontal direction. It is for the purpose of simplifying the figure that seals for the channel 12c of the base 12 are omitted from FIG. 1.

Gaskets 7 for the channel 12c of the base 12, and the relationship thereof with gaskets 7 of the vertical support 14, are depicted i.a. in FIGS. 3A-3B and 4A-4B.

Thus, it is FIGS. 3A-3B and 4A-4B which depict more accurately an EMC gasket 7; 7a, which extends specifically along the mounting frame's base 12 co-directionally with a channel base 12c of one of its base segments, and which during installation comes into contact with the EMC gasket of the vertical support 14 (cf. FIG. 1A).

As can be seen, among others, from FIG. 3B, the gasket 7 thereby constitutes a continuous sealing strip 7″, 7′ extending from the channel 12a in a base segment of the base 12 to the channel 14a of a vertical support 14. The channel 14a of a vertical support 14 and the channel 12a of a base segment are in contact with each other by way of the channel flanges 14d″, 12d′ thereof, which is why the sealing strip extends from the channel flange 12″ of a base segment's channel to the channel flange 14d″ of a vertical support's 14 channel. The benefit gained by such a continuous sealing strip 7″, 7′ is its ability to prevent radio-frequency radiation from propagating across to the opposite side in spite of minor inaccuracies in the manufacturing tolerances of a wall element 31, a base 12 or a vertical support 14 or in spite of slightly out-of-alignment assembly of the base 12 and the vertical support 14, i.e. a deviation from their conventional position normal to each other.

FIGS. 2C-2E present various vertical webs 12g directed upward from a lengthwise plane 12h (horizontal plane) of a base segment of the frame 1.

FIGS. 2K and 2L, on the other hand, depict schematically assemblies made up jointly by a web and a channel in segments of the mounting frame's base 12, as well as in ceiling structures (top support 13) and in a vertical support 14.

In FIGS. 2C-2E are shown, in schematic section views, various webs 12g directed upward from a lengthwise plane 12h (horizontal plane) of a base segment of the frame 1. The webs 12g extend always perpendicularly to the horizontal plane 12h, which is parallel to a foundation on which the base segment is rested. A similar type web 12g may also be included in the top support 13, in which case it extends respectively from the top support and, at the same time, also from a plane of the ceiling perpendicularly downward as depicted in FIG. 2B. A similar type web 12g may also be included in the vertical support 14, in which case the web is vertical and directed sideways from a vertical plane defined by the vertical support 14, towards a base segment fastened to the vertical support 14.

In FIGS. 2K and 2L are respectively illustrated various channels extending in a top or bottom end of the wall element 31 or in an end face of the wall element 31 (cf. FIG. 2B). These can be respectively fitted with a web, an away-directed web connecting to a base segment 21, 22, 23, 24, a top support 13 or a vertical support 14, as presented above schematically in FIG. 2B as well as 2C-2E.

In FIG. 2K is presented how a vertical channel 411 extending in an end face of the wall element 31 can be fitted with a horizontal web 14g of the type shown in FIG. 2C, which protrudes from the vertical support 14. The joint depicted in FIG. 2K can be insulated by placing a seal between the web 14g and a channel flange of the channel 411 extending in an end face of the wall element 31.

FIG. 2L visualizes how a sealing constructed according to the invention is achieved in a joint which is established between vertical webs 12g, included in segments 121 and 122 of the mounting frame's 1 base 12, as well as wall elements 31; 31′ and 31; 31″. Each wall element 31; 31′ and 31; 31″ has its bottom end face 31f formed with a downward-opening channel 311; 311′ and 311; 311″ in which each web 12g; 12g′ or 12g; 12g″, directed upward from a plane of the base's segment 121, 122, is capable of being accommodated. The wall elements 31; 31′ and 31; 31″ are visualized having been installed, by way of the horizontal channels 311; 311′ and 311; 311″ included in the bottom end face 31f thereof, respectively on two webs 12g; 12g′ and 12g; 12g″ rising upward from a plane of the base's 12 base segment 121, 122. The gap between these webs 12g; 12g′ and 12g; 12g″ as well as the horizontal channels 311 in the bottom end faces 31f of the wall element 31; 31′ and 31; 31″ is sealed with an EMC gasket 7, which in this case is an aluminum tape/strip.

In FIG. 2L is further shown an upward-opening horizontal U-channel 311; 311′″ and 311; 311″″ included in a top end of each wall element 31; 31′ and 31; 31″, more specifically in a top side 31d of the top end. These horizontal channels 311; 311′″ and 311; 311″″ at the top ends of the wall elements 31; 31′ and 31; 31″ are fitted with a top support 13 which has two webs 7 directed downward from a plane of this top support 13 (cf. also FIG. 2D). Between the web 13g; 13g′ or 13g; 13g″, directed downward from a plane of the top support 13, and a vertical side of the horizontal channels 311; 311′″ and 311; 311″″ lies a horizontally extending EMC gasket 7; 7a.

The gasket 7; 7a is installed on that vertical side of a wall element's 31 horizontal channel which is closer to a reading carrel T and it extends in a continuous manner in a channel 311 of the wall element's 31 top end 31d as well as in a web 13g of the top support 13. When the channel 311 of the wall element's 31 top end 31d is fitted on the top support's 13 web 13g, the passage of radio-frequency radiation into the reading carrel T by way of the top support's channel 311 is prevented, for example from the side of an adjacent storage. Thus, the sealing strip made up of gaskets 7 extends continuously from a web 13g of the mounting frame's 1 top support 13 to a web 14g (not shown in the figure) of two side supports 14 connected to each top supports, and further to that web 12g of a base segment of the base 12 which comes into contact with these two side supports.

In FIGS. 3A-3B, 4A-4B is also illustrated vertical support pairs 14, 14 installed on segments of the mounting frame's 1 base 12 and having mouths 14b, 14b of the C-channel thereof opening at an angle of either 90 or 180 degrees relative to each other.

FIG. 4C, on the other hand, visualizes a corner of the mounting support's base 12, at which arrive two base segments 121, 122 at a right angle with each other.

FIG. 5 visualizes the construction of a vertical support 14 according to one preferred embodiment of the invention, having its vertical channel 14a provided with an adapter 8 for connecting said vertical support 14 to a horizontal channel 12a or 13a of the base 12 and/or the top support 13.

With these vertical support pairs 14, 14, adapters 8 of the vertical support 14, and segments of the base 12, illustrated in FIGS. 3A-3B, 4A-4B, 4C and 5, there is provided an ability to produce readily and quickly sealable constructions between the mounting frame 1 and the wall elements 31 and door jambs 15 installable thereon. These constructions will be described hereinafter and comprise couplings between interconnected vertical supports and base segments.

FIG. 4C visualizes how the segments 121 and 122 of the base 12 are coupled to each other in such a way that the bottom thereof extend in a common horizontal plane, yet the lengthwise directions thereof are at an angle of 90 degrees, i.e. at a right angle, relative to each other. The right angle between the base segments 121, 122 enables installation at an angle (corner) therebetween of a vertical support pair 14, 14 whose vertical channels 14a, 14a open at an angle of 90 degrees relative to each other as illustrated in FIGS. 3B and 4A.

A corner of the base 12, visible in FIG. 4C, is assembled from two base segments 121 and 122 of the base 12 by coupling the same to each other for a 90-degree angle. Each base segment 121, 122 of the base 12, and at the same time the entire base 12 as well, is made up of a channel beam 120. The channel beam 120 has its channel 12a made up of a channel base 12c whose both lengthwise sides are provided with channel flanges 12d; 12d′ and 12d; 12d″ directed away from the channel base, each extending in a direction which is transverse to that of said channel base 12c. Close to an upper edge of one of the channel beam's 120 channel flanges 12d; 12d′ extends a continuous elongated, strip-like gasket 7 manufactured from an electrically conductive material such as metal. The gasket 7 follows said upper edge of the channel flange 12d; 12d′, extending thereby in a lengthwise direction of the channel base. The gasket 7 extends along the channel beam 120 preferably from end to end.

FIGS. 3B and 4A visualize a vertical support pair 14; 14′ and 14; 14″ already fitted in the channels 12a of two base segments 121, 122 of the base 12, said vertical supports having mouths 14b, 14b′ and 14b; 14b″ thereof opening at an angle of 90 degrees relative to each other. FIG. 3A shows, on the other hand, how the vertical support pair 14; 14′ and 14; 14″ is mounted on the base segments 121, 122 of the base 12 present at a 90-degree angle relative to each other. The base's segments 121, 122 are coupled to each other the same way as described above in reference to FIG. 4C.

FIG. 4B reveals, on the other hand, two vertical supports 14; 14′ and 14; 14″ installed in a channel 12a of a single base segment 121 of the base 12, with mouths 14b, 14b thereof opening at an angle of 180 degrees relative to each other. Such a vertical support pair 14′, 14″ is mounted on the middle part of a base segment and can be used for example as an interim support for the installation of a door 5 on the mounting frame's base segment so as to be subsequently illustrated in FIG. 7B.

The rear flanges of vertical support pairs 14; 14′ and 14; 14″ displayed in FIGS. 3A-3B as well as 4A-4B can be coupled to each other prior to installation. Each vertical support 14′, 14″ of the vertical support pair 14; 14′ and 14; 14″, made up of inter-connected vertical supports and presented in FIGS. 3A-3B as well as 4A-4B, consists of a channel beam 140 identical to that described above in reference to FIGS. 1A and 1B. The construction of a channel beam 120 of the base segments displayed in FIGS.

3A-3B as well as 4A-4B, on the other hand, is identical to what has been more precisely described in reference to FIG. 4C.

FIG. 5 reveals the construction of a vertical support 14 according to one preferred embodiment of the invention, said vertical support being provided with an adapter for coupling the vertical support 14 to a base 12 and/or a top support 13. This has been demonstrated with two identical, longitudinally interconnected vertical supports 14; 14′ and 14; 14″ visible in FIG. 5, each of which is made up of a channel beam 140. The construction of channel beams 140; 140′ and 140; 140″ is identical to what has been described earlier in connection with FIG. 1A. Above a top edge of the lower part (or upper part) or a top end face 14f (of the lower part) of each channel beam 140; 14′ and 140; 140″ 140 rises an end face adapter 80 visible in the figure. Said vertical supports 14; 14′ and 14; 14″ are connected to each other the same way as those illustrated in FIGS. 3A-3B as well as 4A-4B, whereby the first vertical support 14; 14′ has the rear wall of its channel flange 14d coupled to the rear wall of the second vertical support's 14; 14″ channel base 14c.

The end face adapter 80 is part of an adapter 8 already fixed to a channel 14a of the vertical support 14, whereby the vertical support 14 is attachable to the base 12. The adapter 8 includes an inner adapter, as well as the end face adapter 80 shown in the figure. The end face adapter protrudes from outer edges 14f, 14f of the end faces of a channel base 14c and channel flanges 14d, 14d of the channel 14a of a channel beam 140 employed as the vertical support 14 co-directionally with the channel 14a over a certain distance (protruding distance) 80h. The end face adapter 8; 80 has its protruding distance 8h matching the depth of a channel 12a of the base 12 or a channel 13a of the top support 13, i.e., in practice, the vertical width of channel flanges 12d or 13d of the base's channel 12a or the top support's channel 13a. Here, the vertical support 14 has the length of its EMC gasket 7; 7a slightly exceeding that of the channel flanges 14d and channel base 14c of the vertical support 14. Hence, the gasket 7; 7a extends from a top edge (outer edge) 14f of the vertical support's 14 channel flange 14d to about a midpoint of the length (protruding distance) 80h of the end face adapter 80.

The vertical support 14 is mounted on a channel beam 120 of the base 12 by means of said adapter 8 in such a way that the end face adapter 80 has a bearing surface 80a of its end face rested against a channel base 12c of the base's channel 12a or against a channel base 13c of the top support's 13 channel 13a. Hence, the gasket 7; 7a, which is co-directional with a channel flange 14d of the vertical support 14, extends to a gasket 7 extending along a flange 12d or 13d of the base 12 or the top support 13 and following a top edge of the flange. Thus, the gasket 7; 7a has its length designed to be such that it extends all the way of a horizontal gasket 7 extending along a channel flange 12d or 13d of the base's 12 or top support's 13 channel beam 120 or 130.

Provided that the vertical support 14 has top and bottom ends of its channel beam 140 fitted with an end face support 80, 80, there will be a capability of resting a lower end face adapter 80 of the channel beam 140 against a channel base 12c of the base's 12 base segment 12a and of resting an upper top adapter 80 against a channel 13c of the top support's 13 channel 13a. Thereby, the vertical support 14 has its gasket 7; 7a, which is co-directional with the channel flange 14d, extending all the way to a gasket 7 extending along a flange 12d the base 12 as well as along a channel flange 13d of the top support 13 and following a top edge of the flange 12d and 13d. This way is provided a continuous sealing strip 70 from base segments of the base 12 along a vertical support 14 and further to a top support 13.

FIG. 6 displays an arrangement used for leveling the base 12. There, underneath a bottom of the mounting frame's base 12 is installed an auxiliary mounting frame 9 such as a rigid metal foil. This is followed by adjusting orientation of the mounting frame's base with respect to the ground or the foundation of a building with screws bearing against the auxiliary mounting frame as well as with a spring retained between the screws.

In FIGS. 7A and 7B there is respectively displayed two wall elements 31; 31′ and 31; 31″ for the wall 3 (FIG. 7A) as well as a wall element 31 and a door 5 (FIG. 7B), mounted on a pair of vertical supports 14; 14′ and 14; 14″ present in a corner formed by segments 121 and 122 of the base 12.

Hence, the vertical supports 14; 14′ and 14; 14″ made up of channel beams 140 have mouths thereof opening at an angle of 90 degrees away from each other co-directionally with a channel base 12c, 12c of the base segments 121 and 122 of the base 12 likewise made up of channel beams. This structure, composed of interconnected pairs of vertical supports 14; 14′ and 14; 14″ and base segments 121, 122 of the base 12, is similar to what has been displayed earlier in FIGS. 1A-1B, 3B and 4B, 4C. Thus, each vertical support of the pair of vertical supports 14; 14′ and 14; 14″ consists of interconnected channel beams 140′, 140″ whose construction is similar to what has been described earlier for example in reference to FIGS. 1A and 1B. Likewise, each of both base segments 121 as well as 122 of the base consists of channel beams 120 whose construction is similar to what has been described earlier for example in reference to FIGS. 1A and 1B.

In FIG. 7A, each wall element 31; 31′ and 31; 31″ is coupled to the mounting frame 1, which includes not only the aforesaid pair of vertical supports 14; 14′ and 14; 14″ present at an angle or corner formed by the base segments 121, 122 but also a vertical support 14, which is coupled to an end face of each base segment 121 and 122 and which has its mouth 14b turned perpendicularly towards a vertical support present at the other end of the base segment. In the exemplary FIG. 7A is only shown, seen in a direction from the pair of vertical supports 14; 14′ and 14; 14″, a third vertical support 14; 14′″ coupled to one end face 121a of the base segment 121. The vertical support 14; 14′″ consists of a channel beam 140′″ whose construction is similar to what has been described earlier for example in reference to FIGS. 1A and 1B. The vertical support 14′″ has its mouth 14b′″ turned directly towards the vertical support 14; 14′ present at an opposite end of the base's 12 segment 121.

In addition, the mounting frame 1 comprises a horizontal top support, not shown, which connects to top ends of the vertical supports 14; 14′ and 14; 14″ via an end face adapter (not shown in the figures) present at the vertical supports' top end.

Each channel beam 120; 120′ and 120; 120″ making up the base segments 121 and 122 for the base 12 is fitted with a radio-frequency interference suppressing gasekt 7, preferably an EMC gasket. The gasket 7 extends co-directionally (in horizontal direction) with a channel base of the relevant channel beam 120′ and 120″ along the channel beam 120′ and 120″ from end to end. One of the channel flanges (12d, 14d) of a channel (12a, 14a) in a channel beam 140; 140′, 140″ and 140′″ making up each vertical support 14; 14′, 14″ and 14″ is also fitted with a radio-frequency interference suppressing gasket 7 such as an EMC gasket. The gasket 7 extends co-directionally with a channel base 12c, 14c of each vertical support 140; 140′, 140″ and 140′″, i.e. in vertical direction, extending to end face adapters (not shown in the figure) present at bottom and top ends of the channel beam 140; 140′, 140″ and 140′″ making up each vertical support 14; 14′, 14″ and 14′″ as illustrated in FIG. 5.

The vertical supports 14; 14′, 14″ and 14′″ are mounted on the channel beams 120; 120′ and 120; 120″ of base segments of the base 12 by means of end face adapters 80 included in bottom ends of the vertical supports 14; 14′, 14″ and 14′″. In addition, each vertical support 14; 14′, 14″ and 14′″ is coupled to horizontal top supports, not shown in FIG. 7A, by means of an end face adapter (not shown in the figures) included in a top end of each vertical support. The vertical supports 14; 14′, 14″ and 14′″ are also coupled, as depicted in FIG. 5, i.e. by means of an end face adapter 80, to the channel beams 120; 120′ and 120; 120″ the base's 12 base segments and to said top supports. Thus, the gasket 7, which is co-directional with a channel flange 14d of each vertical support 14; 14′, 14″ and 14′″, extends all the way to a gasket 7 which extends along a flange 12d or 13d of the base 12 or the top support 13, following a top edge of the flange 12d or 13d. The gasket 7; 7a is designed in such a way in terms of its length that it extends all the way to an elongated gasket 7 extending along a channel beam 120 of the base's base segment or a channel beam 130 of the top support 13.

Accordingly, the gasket 7, which is co-directional with a channel flange 14d of each vertical support 14; 14′, 14″ and 14′″, extends all the way to a seal which extends along a flange 12d of the base's 12 base segment 121 or 122, as well as along a channel flange 13d of the top support 13, following a top edge of the channel flange. Thereby is provided a continuous sealing strip, which extends from each base segment 121, 122 of the base to each vertical support 14; 14′, 14″ and 14′″ mounted on these base segments, and further to the top support 13.

Each wall element 31; 31′ and 31; 31″ has its bottom end now fitted in a channel 12c of the base segment 121 or 122 included in the mounting frame's 1 base 12. On the other hand, each wall element 31; 31′ and 31; 31″ has both of its end faces, and side faces adjoining these end faces, fitted in channels 14a of the mounting frame's vertical supports 14; 14′, 14″ and 14′″. Each wall element 31; 31′ and 31; 31″ has its top end face fitted in top supports (not shown in the figures) following the base segments 121, 122. Thereby, the radio-frequency interference suppressing seals 7 make up a continuous sealing strip, which extends from each base segment 121, 122 of the base to each vertical support 14; 14′, 14″ and 14′″ and further to the top support 13. This sealing strip is also supported on a bottom end of each wall element 31, on a side face adjoining each vertical side, and on a top end of the wall element, thereby making up a continuous sealing strip encircling an outer edge of the wall element's front side.

FIG. 7B illustrates part of a mounting frame 1 of the invention provided with a door 5. The mounting frame 1 includes first of all two base segments 121, 122, which are coupled to each other at an angle of 90 degrees and thereby is obtained a corner of the base 12. The constructions of the base's 12 base segments 121, 122, making up a corner of the base, and seals 7 attached thereto, are similar to those depicted earlier in FIG. 4C.

In a channel 12a of these two base segments 121, 122 of the base 12 is installed a pair of vertical supports 14; 14′ and 14; 14″, said vertical supports having mouths 14b, 14b′ and 14b; 14b″ thereof opening at an angle of 90 degrees relative to each other as presented in FIG. 3A. A seamless sealing strip encircles from each base segment 121, 122 to the vertical supports 14; 14′ and 14; 14″ as illustrated in FIGS. 3A-3B and 4A-4B. The electrically conductive EMC gasket 7, such as an aluminum strip, extends along the base segment 121, 122 of the base 12 co-directionally with a channel base 12c. When the base segment 121, 122 comes into contact with the vertical supports 14; 14′ and 14; 14″ (cf. FIG. 1A), the result will be a continuous sealing strip extending from the base segment 121, 122 of the base 12 to each vertical support 14.

In addition, the base 12 is provided with two vertical supports 14 and 14, which are installed in a channel 12a of a single base segment 121 of the base 12, and whose mouths 14b, 14b are opening at an angle of 180 degrees relative to each other (cf. FIG. 4B). Along one flange of the base's base segment 121 extends a seal, preferably an EMC gasket, which extends co-directionally with its channel base 12c and which, during installation, comes into contact with the EMC gasket of the vertical supports 14, 14 (cf. FIG. 1A). Thereby is obtained a continuous sealing strip encircling from the channel 12a of the base segment 121 of the base 12 to each channel 14b of the vertical support 14, 14.

This pair of vertical supports 14, 14, installed in the channel 12a of a single base segment 121, can be used for example as an intermediate support for mounting a door 5 as follows:

A door frame 51 has its bottom piece 51a fitted in a channel 12a present in a base segment 121 of the mounting frame's 1 base 12. The door fame 51 has its first side piece 51b fitted in one of the vertical supports 14; 14′ of a pair of vertical supports. The door frame 51 has its second side piece fitted, on the other hand, in the other of the vertical supports 14 installed in the channel 12a of the base's same base segment 121. Hence, the radio-frequency interference suppressing gasket 7 is able to support itself respectively on the bottom piece of the door frame 51 and on each side piece 51b, 51b of the door frame 51. The mounting frame 1 further includes a horizontal door frame support 15 which is coupled to the two vertical supports.

A head piece 51c of the door frame can be installed on said door frame support: the horizontal door frame support 15 is made up of a channel beam 150, having its channel 15a consisting of a channel base 15c whose both longitudinal sides are provided with channel flanges 15b directed away from said channel base 15c, each additionally extending in a direction which is transverse to that of said channel base 15c. The door frame support 15 has one of its channel flanges 15b; 15b′, 15b″ fitted with a radio-frequency interference suppressing EMC gasket, which extends co-directionally with the channel beam's 150 channel base 15c. Therefore, the door frame support 15 has a basic structure similar to those of the vertical support 14 as well as the segment of the base 12, both of which are also made up of channel beams 140, 120.

The door frame support 15 connects to a midsection or top end of the vertical supports 14. Its first end connects to one of the vertical supports 14; 14′ of a pair of vertical supports and its second end connects in turn to the other of the vertical supports 14 installed in the channel 12a of the base's same base segment 121.

The door frame has its head piece 51c fitted in a channel (15c) of the mounting frame's 1 door frame support 15 in such a way that the radio-frequency interference suppressing gasket 7 supports itself also on the door frame's head piece.

FIGS. 8A-8D display various RFID-carrels, which have been constructed with a base and pairs of vertical supports providing an insulation of the invention.

First of all, these figures display a reading carrel 100 for RFID tags, which is located in a transportable container (FIG. 8A) and accompanied by a storage space for RFID tags and two doors 5 into an interior of the reading carrel 100. The reading carrel is provided with reading means 6 for RFID tags, comprising an antenna as well as a data processing system by way of which there is provided a capability of reading RFID tags to be retrieved from the storage. The storage is located outside of the reading carrel 100 and, thus, no error signals should be allowed therefrom into the reading carrel. Each door 5 to the reading carrel and all wall elements 31; 31′, 31″, 31′″, 31″″ and ceiling of the wall 3 are arranged in a previously described support frame consisting of channel beams and comprising a base 12, vertical supports 14, top supports 13, and door frame supports 14. The channel beams, included in the mounting frame 1 (=support frame), in a base, in vertical supports, in top supports, and in door frame supports, have the channel flange thereof, which is closer to the reading carrel interior, always provided with an encircling continuous sealing strip which has been made of an EMC gasket. The mounting frame 1 and the wall elements fitted thereto have already been installed on the container floor.

FIGS. 8B and 8C display a reading carrel 100 for RFID tags, which is located adjacent to a storage space or a shop carrying objects equipped with RFID tags. In the shop, the door 5 can be a sliding door.

In addition, FIG. 8D shows the use of a reading carrel 100 for controlling the passage of persons carrying RFID tags.

FIG. 9 shows still another reading carrel 100 for RFID tags, which is provided with a glass door. The reading carrel displayed in FIG. 9 has been implemented as described in FIG. 7B and it comprises a base 12, which includes segments 121 and 122 for the base 12, each of which is made up of a channel beam 120 having a top edge of one channel flange thereof traced by a continuous EMC gasket of electrically conductive material. To the segments 121, 122 of the base 12 is connected a plurality of vertical support pairs 14, 14, each consisting of a channel beam 140. To a top end of these pairs of vertical supports is coupled a door frame support 15 as well as a top support 13, both of which are likewise made up of channel beams. Each vertical support 14 of the pair of vertical supports 14, 14, as well as the door frame support 15, are also provided with a continuous EMC gasket as described previously. The EMC gasket encircles in the form of a continuous sealing strip from a first segment 121 of the base to the vertical supports of a vertical support pair 14, 14 located at a corner of the segments 121, 122, as well as to the vertical supports of a second vertical support pair 14, 14 located on the base's segment 121, and further to the door frame support 15 and to the top support. In addition, the EMC gasket encircles in the form of a continuous sealing strip from a second segment 122 of the base 12 to each vertical support 14 of a vertical support pair 14, 14 located at a corner of segments 122 and 123, as well as further to the top support 13. By fitting the glass door, as depicted in FIG. 7B, in the channel of a channel beam 140 of a pair of vertical supports 14, 14, in the channel of a base segment 121, as well as in the channel of a door frame support 15, there is established a structure with the glass door resting by one of its outer edges against the continuous sealing strip. Each wall 31 is installed, as depicted in FIGS. 7A and 7B, in the channel of a segment for the base 12, in the channel of two vertical supports 14 present at opposite ends of the segment, as well as in the channel of a top support 13 connecting these vertical supports. Thereby, each wall is enabled to bear by one of its outer edges against a continuous sealing strip, which extends from a top edge of the base segment's channel flange to a top edge of both vertical supports' channel flanges, and further to a top edge of the top support's channel flange.

### LIST OF REFERENCE NUMERALS

Mounting frame 1
base 12
   channel 12a
   mouth 12b
   channel base 12c
   channel flanges 12d
   web 12g
   lengthwise horizontal plane of the base 12h
base segment 121, 122, 123, 124
channel beam 120
top support 13
   channel 13a
   channel base 13c
   channel flange 13d
   web 13g
   channel beam 130
vertical support 14
   channel 14a
   mouth 14b
   channel base 14c
   channel flange 14d
   rear face 14e
   top or bottom edge (outer edge) 14f
   web 14g
   vertical channel 141
   channel beam 140
door frame support 15
   channel 15a
   channel base 15c
   channel flanges 15d
channel beam 150

Ceiling 2

Wall 3
wall element 31
   end face 31a
   side face adjoining the end face 31e
   front side 31b
   rear side 31c
   top side 31d
   bottom side, bottom end face 31f
   channel 311
   channel base 311c
   channel flange 311d

Floor 4

Door 5
door frame 51
   bottom piece of the door frame 51a
   side piece of the door frame 51b
   head piece of the door frame 51c

Reading means 6

Radio-frequency radiation suppressing gasket 7

EMC gasket 7a

Adapter 8
End face adapter 80
end face adapter bearing surface 80a
end face adapter protruding distance 80h
Inner adapter 90

Auxiliary mounting frame 9

Reading carrel 100
interior T

1. A reading carrel for RFID tags, having a ceiling, a floor, at least one door, as well as walls encircling the reading carrel and including a plurality of interconnected wall elements, as well as a mounting frame for the walls and the at least one door as well as means for reading RFID tags in the reading carrel, wherein the reading carrel has
a mounting frame comprising a horizontal base extending around an interior (T) of the reading carrel and consisting of a plurality of interconnected base segments, said horizontal base being connected with a plurality of vertical supports, wherein
each base segment of the mounting frame is made of a channel beam and each vertical support is also made of a channel beam, said channel beams having channels thereof consisting of a channel base which is provided on both sides with channel flanges directed away from said channel base, each channel flange extending in a direction transverse to that of said channel base,
each wall element of the wall has its lower end fitted in the channel of the mounting frame's base and, moreover, each wall has both end faces thereof fitted in the channel of the mounting frame's vertical support,
between at least one base segment as well as a lower end of the wall element mounted thereon is fitted a radio-frequency interference suppressing seal, such as an EMC gasket, which extends co-directionally with the channel base of a channel beam comprising said base segment, whereby between at least one vertical side face adjoining at least one end face of a wall element mounted on said base segment and the channel flange of the channel of the channel beam comprising the vertical support mounted on the very same base segment is likewise fitted a radio-frequency interference suppressing seal, such as an EMC gasket, which extends co-directionally with the channel base of the channel beam comprising said vertical support, such that the aforesaid radio-frequency interference suppressing seal extends in a substantially continuous manner from the base segment to the channel flange of at least one vertical support, and
reading means for RFID tags comprise an antenna as well as a data processing system, both of which provide a capability of reading RFID tags.

2. The reading carrel according to claim 1, which has at least one door including a door element as well as a door frame encircling the door element, wherein the door frame has its bottom piece fitted in the channel of a base segment of the mounting frame's base, and that the door frame has each side piece thereof fitted in the channel of a vertical support of the mounting frame, whereby at least one elongated radio-frequency interference suppressing seal is installed respectively between the bottom piece of the door frame and the channel of the base segment, as well as at least one elongated radio-frequency interference suppressing seal is also installed between each side piece of the door frame and the channel of the vertical support.

3. The reading carrel according to claim 1, wherein the at least one door is a sliding door which is fitted in the channel of a base segment of the mounting frame's base.

4. The reading carrel for RFID tags according to according to claim 1, wherein the mounting frame further comprises a top support co-directional with the mounting frame's base and associated with a top end of the vertical supports, and said top support consists of a channel beam, the top support having its channel made up of a channel base which is provided on both sides with channel flanges directed away from the channel base, each in a direction transverse to that of said channel base, whereby
each wall element of the wall has its top end fitted in the channel of the mounting frame's top support, and
between at least one channel flange of the top support and a top end of the wall element is installed a radio-frequency interference suppressing seal, such as an EMC gasket, which extends co-directionally with the channel beam's channel base.

5. The reading carrel for RFID tags according to claim 1, wherein
the mounting frame further comprises a horizontal door frame support, which is associated with a midsection or top end of the vertical supports, and which door frame support consists of a channel beam whose channel is made of a channel base provided on both sides thereof with channel flanges directed away from the channel base, each extending in a direction which is transverse to that of said channel base, whereby
the door frame support has at least one of its channel flanges fitted with a radio-frequency interference suppressing seal, such as an EMC gasket, which extends co-directionally with the channel base, and
the door frame's head piece is fitted in a channel of the mounting frame's door frame support in such a way that the aforesaid radio-frequency interference suppressing seal is also supported on the door frame's head piece.

6. The reading carrel for RFID tags according to claim 1, wherein the first radio-frequency interference suppressing seal extends in a continuous manner fra channel flange of the channel in the base of the mounting frame to a channel flange of the channel in two vertical supports associated therewith, and further to a channel flange of the channel in a possible top support.

7. The reading carrel for RFID tags according to claim 6, wherein the second radio-frequency interference suppressing seal extends in a continuous manner from a channel flange of the channel in the base of the mounting frame to a channel flange of the channel in a vertical and further to a channel flange of the channel in the door frame support.

8. The reading carrel for RFID tags according to claim 1, wherein the vertical support (14) is made up of two channel beams in contact with each other.

9. The reading carrel for RFID tags according to claim 8, wherein the channel beams have mouths of the vertical channels thereof opening in opposite directions.

10. The reading carrel for RFID tags according to claim 8, wherein the channel beams have mouths of the vertical channels thereof directed at an angle of 90 degrees relative to each other.

11. The reading carrel for RFID tags according to claim 8, wherein the channel beams are attached to each other or integrated for a single piece.

12. The reading carrel for RFID tags according to claim 1, wherein the channel of the vertical support opens in a lengthwise direction of the base segment of the mounting frame's base.

13. The reading carrel for RFID tags according to claim 1, wherein the vertical support comprises a channel beam, provided at its bottom and/or top end with an adapter for installing said vertical support in the channel of a base segment of the mounting frame's base and/or in the channel of the top support.

14. The reading carrel for RFID tags according to claim 13, wherein the seal lengthwise of the vertical support extends to a channel of the base and/or to the channel of the top support.

15. A reading carrel for RFID tags, having a ceiling, a floor, at least one door, as well as walls encircling the reading carrel and including a plurality of interconnected wall elements, as well as a mounting frame for the walls and the door/doors, as well as means for reading RFID tags in the reading carrel, wherein the reading carrel has
mounting frame comprising a horizontal base extending around an interior (T) of the reading carrel and consisting of a plurality of interconnected base segments, said base being provided with a plurality of vertical supports, each base segment as well as vertical support of the mounting frame being respectively made of a beam provided with a web which is directed upwards from the beam's horizontal plane or sideways from the beam's vertical plane and which extends in a longitudinal direction of the discussed beam,
the bottom end as well as both end faces of its wall element provided with an elongated channel which is made up of a channel base provided on both sides thereof with channel flanges directed away from the channel base, each extending in a direction transverse to that of said channel base, whereby
the wall has the channel of a bottom end of its wall element and the channel of each end face of its wall element fitted on the web of the mounting frame,
between the bottom end channel of each wall element and the web of a base segment of the mounting frame is fitted at least one radio-frequency interference suppressing seal, such as an EMC gasket, which extends co-directionally with a channel base of said channel, and
between the channel of each end face and the web of a respective vertical support is also fitted at least one radio-frequency interference suppressing seal, such as an EMC gasket, which extends in a lengthwise direction of the vertical support,
reading means for RFID tags comprise an antenna as well as a data processing system, both of which provide a capability of reading RFID tags.

16. The reading carrel according to claim 1, having at least one door including a door element as well as a door frame encircling the door element, wherein the door frame has its bottom piece and each side piece of the door frame provided with a channel, which is made up of a channel base having both sides thereof provided with channel flanges directed away from the channel base, each extending in a direction transverse to that of said channel base, and
at least one of the channel flanges of a channel in the bottom piece of the door frame and at least one of the channel flanges of each side piece thereof is fitted with a radio-frequency interference suppressing seal, such as an EMC gasket, which extends co-directionally with said channel base, whereby
each side piece of the door frame is fitted on a web of the mounting frame's vertical support in such a way that the aforesaid at least one radio-frequency interference suppressing seal is also in contact with the web of the mounting frame's vertical support,
the door frame has its bottom piece fitted on a base segment in such a way that the aforesaid at least one radio-frequency interference suppressing seal is also in contact with the web of the base segment of the mounting frame's base.

17. The reading carrel according to claim 15, wherein the door is a sliding door, which fitted on a web rising from a base segment of the mounting frame's base.

18. The reading carrel for RFID tags according to claim 15, wherein
the mounting frame further comprises a top support, which is co-directional with the base of the mounting frame and associated with a top end of the vertical supports, and said top support consists of a beam which includes a web directed downward from the beam's horizontal plane and extending co-directionally with a longitudinal direction of the top support, whereby the wall has a top end of its wall elements and/or the door frame has a top end of its head piece provided with an elongated channel, which is made up of a channel base provided on both sides thereof with channel flanges directed away from the channel base, each extending in a direction transverse to that of said channel base,
each wall element of the wall has its top end channel and/or the door frame has the top end channel of its head piece fitted on said web of the mounting frame's top support,
between at least one channel flange of the top end channel of each wall element of the wall and the web of the top support is fitted an elongated radio-frequency interference suppressing seal, such as an EMC gasket, which extends co-directionally with the top end channel of said wall element

19. The reading carrel for RFID tags according to claim 15, wherein the radio-frequency suppressing seal extends in a continuous manner from the web of a base segment of the mounting frame's base to the web of a vertical support associated with two base segments, and further to the web of a possible top support.

20. The reading carrel for RFID tags according to claim 19, wherein the radio-frequency suppressing seal extends in a continuous manner from a bottom end face of the wall to each side face of the wall.

21. The reading carrel for RFID tags according to claim 18 wherein the radio-frequency suppressing seal extends in a continuous manner from the web of a base segment of the mounting frame's base to the web of a vertical support, and further to the web of a door frame support.

22. The reading carrel for RFID tags according to claim 15, wherein two vertical supports are coupled to each other in such a way that the webs thereof are directed in opposite directions.

23. The reading carrel for RFID tags according to claim 15, wherein two vertical supports are coupled to each other in such a way that the webs thereof are directed at an angle of 90 degrees relative to each other.

24. The reading carrel for RFID tags according to claim 1, wherein under the mounting frame's base is installed an auxiliary mounting frame for adjusting direction of the mounting frame's base with respect to the ground or the foundation of a building.

25. The reading carrel for RFID tags according to claim 1, wherein the radio-frequency interference suppressing seal is a metal gasket.

26. reading carrel for RFID tags according to claim 1, wherein the radio-frequency interference suppressing seal is made of a metal such as aluminum, and designed with mutually form-locking shapes for base segments of the mounting frame's base and for vertical supports of the mounting frame, as well as for wall elements of the wall to be coupled thereto.

27. The reading carrel (100) for RFID tags according to claim 1, wherein the reading carrel is located in a transportable container.

28. The reading carrel for RFID tags according to claim 1, wherein the reading carrel is located in the proximity of a storage space or shop, said storage or shop carrying objects provided with RFID tags.

29. A method to control entries and ecits of persons in possession of RFID tags, said method comprising using a reading carrel for RFID tags according to claim 1.
